(19) United States
(12) Patent Application Publication
(10) Pub. No.: US 2025/0263838 A1
(43) Pub. Date: Aug. 21, 2025

(54) SURFACE COATING FOR PLASMA PROCESSING CHAMBER COMPONENTS

(71) Applicant: Lam Research Corporation, Fremont, CA (US)

(72) Inventors: Slobodan MITROVIC, Oakland, CA (US); Jeremy George SMITH, Oakland, CA (US); Tony Shaleen KAUSHAL, Campbell, CA (US); Eric A. PAPE, Santa Cruz, CA (US)

(21) Appl. No.: 19/203,736

(22) Filed: May 9, 2025

Related U.S. Application Data
(62) Division of application No. 17/261,812, filed on Jan. 20, 2021.
(60) Provisional application No. 62/703,698, filed on Jul. 26, 2018.

(51) Int. Cl. C23C 16/44; C23C 16/40; C23C 16/455; C25D 11/24; H01J 37/32

(52) U.S. Cl. CPC C23C 16/4404; C23C 16/40; C23C 16/45527; C23C 16/45555; C25D 11/24; H01J 37/32495

(57) ABSTRACT

A method for coating a component of a plasma processing chamber is provided. An electrolytic oxidation coating is formed over a surface of the component, wherein the electrolytic oxidation coating has a plurality of pores, wherein the electrolytic oxidation coating has a thickness and at least some of the plurality of pores extends through the thickness of the electrolytic oxidation coating. An atomic layer deposition is deposited on the electrolytic oxidation coating. The atomic layer deposition comprises a plurality of cycles, where each cycle comprises flowing a first reactant, wherein the first reactant forms a first reactant layer in the pores of the electrolytic oxidation coating, wherein the first reactant layer extends through the thickness of the electrolytic oxidation coating, stopping the flow of the first reactant, flowing a second reactant, wherein the second reactant reacts with the first reactant layer, and stopping the flow of the second reactant.

### CROSS REFERENCE TO RELATED APPLICATION

This application is a Divisional of U.S. application Ser. No. 17/261,812, filed Jan. 20, 2021, which claims a 371 of international Application No. PCT/US2019/042569, filed Jul. 19, 2019, which claims priority of U.S. Application No. 62/703,698, filed Jul. 26, 2018, which is incorporated herein by reference for all purposes.

### BACKGROUND

The present disclosure relates to the manufacturing of semiconductor devices. More specifically, the disclosure relates to plasma chamber components used in manufacturing semiconductor devices.

During semiconductor wafer processing, plasma processing chambers are used to process semiconductor devices. Components of plasma processing chambers are subjected to plasmas and arcing. The plasmas and arcing may degrade the components.

### SUMMARY

To achieve the foregoing and in accordance with the purpose of the present disclosure, a method for coating a component of a plasma processing chamber is provided. An electrolytic oxidation coating is formed over a surface of the component, wherein the electrolytic oxidation coating has a plurality of pores, wherein the electrolytic oxidation coating has a thickness and at least some of the plurality of pores extend through the thickness of the electrolytic oxidation coating. An atomic layer deposition is deposited on the electrolytic oxidation coating, using an atomic layer deposition process. The atomic layer deposition process comprises a plurality of cycles, where each cycle comprises flowing a first reactant, wherein the first reactant forms a first reactant layer in the pores of the electrolytic oxidation coating, wherein the first reactant layer extends through the thickness of the electrolytic oxidation coating, stopping the flow of the first reactant, flowing a second reactant, wherein the second reactant reacts with the first reactant layer, and stopping the flow of the second reactant.

In another manifestation, a component adapted for use in a semiconductor processing chamber is provided. An electrolytic oxidation coating is on a surface of a component body, wherein the electrolytic oxidation coating has a plurality of pores, wherein the electrolytic oxidation coating has a thickness and at least some of the plurality of pores extend through the thickness of the electrolytic oxidation coating. An atomic layer deposition fills the plurality of pores of the electrolytic oxidation coating.

In another manifestation, a method for coating a component of a plasma processing chamber is provided. A ceramic coating is formed over a surface of the component, wherein the ceramic coating has a plurality of pores, wherein the ceramic coating has a thickness and at least some of the plurality of pores extend through the thickness of the ceramic coating. An atomic layer deposition is deposited on the ceramic coating using an atomic layer deposition process, wherein the atomic layer deposition process comprises a plurality of cycles, wherein each cycle comprises flowing a first reactant gas, wherein the first reactant gas forms a first reactant layer in the pores of the ceramic coating, wherein the first reactant layer extends through the thickness of the ceramic coating, stopping the flow of the first reactant gas, flowing a second reactant gas, wherein the second reactant gas reacts with the first reactant layer, and stopping the flow of the second reactant gas. Some of the atomic layer deposition is polished away.

In another manifestation, a component adapted for use in a semiconductor processing chamber is provided. A ceramic coating is over a surface of a component body, wherein the ceramic coating has a plurality of pores, wherein the ceramic coating has a thickness and at least some of the plurality of pores extend through the thickness of the ceramic coating. An atomic layer deposition fills the plurality of pores of the ceramic coating. A surface of the atomic layer deposition is polished.

In another manifestation, a method for coating a component of a plasma processing chamber is provided. An electrolytic oxidation coating is formed over a surface of the component. A spray coating is deposited over the electrolytic oxidation coating.

In another manifestation, a component adapted for use in a semiconductor processing chamber is provided. An electrolytic oxidation coating is over a surface of a component body. A spray coating is over the electrolytic oxidation coating.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIGS. 2A-C are schematic views of a component processed according to an embodiment.

FIG. 3 is a schematic view of an etch reactor that may be used in an embodiment.

FIG. 4 is a high level flow chart of another embodiment.

FIGS. 5A-C are schematic views of a component processed according to an embodiment.

FIG. 6 is a high level flow chart of another embodiment.

FIGS. 7A-B are schematic views of a component processed according to an embodiment.

### DETAILED DESCRIPTION

The present disclosure will now be described in detail with reference to a few embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

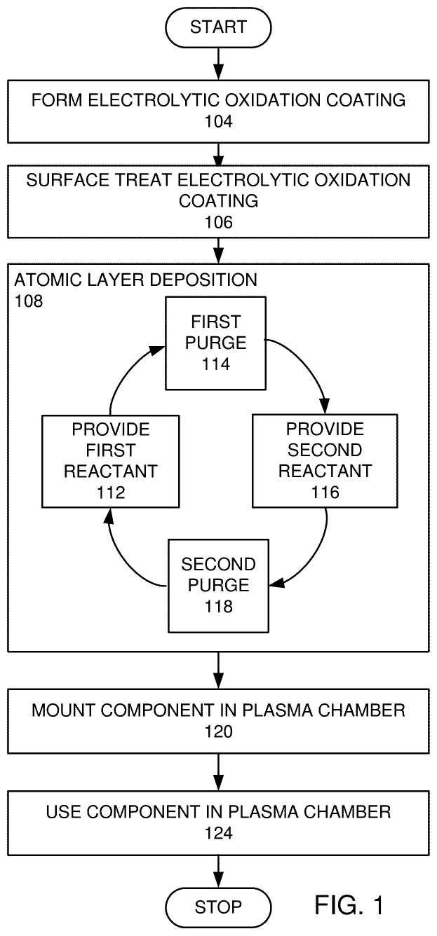

To facilitate understanding, FIG. 1 is a high level flow chart of a process used in an embodiment. In an example of an embodiment, an electrolytic oxidation coating is formed on a surface of a component (step 104). Electrolytic oxidation is also known as plasma electrolytic oxidation (PEO) and electrolytic plasma oxidation (EPO) or microarc oxidation (MAO). Electrolytic oxidation is a method of generating oxide coatings on metals. Electrolytic oxidation uses AC voltage of higher potential than anodization to create a discharge and in the case of PEO/EPO plasma discharge that provides an electrolytic oxidation coating of a crystalline metal oxide layer with interconnected and surface-connected pores that extend through the thickness of the electrolytic oxidation coating.

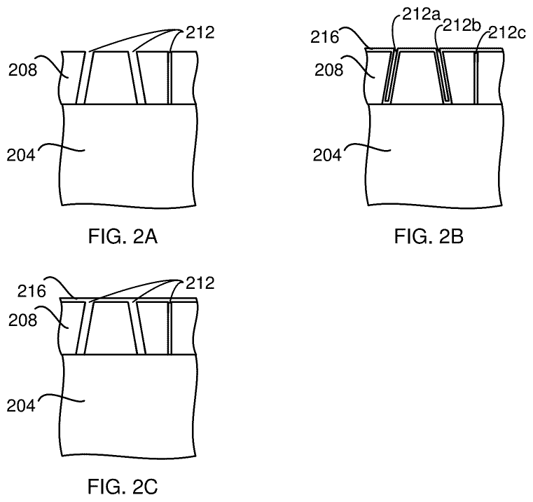

FIG. 2A is a schematic cross-sectional view of a component body 204 with an electrolytic oxidation coating 208. The electrolytic oxidation coating 208 has a plurality of pores 212, where some of the pores 212 create openings. The openings extend through the thickness of the electrolytic oxidation coating 208 to the surface of the component body 204. The pores 212 are not drawn to scale but are shown with an enlarged width in order to better illustrate the working of this embodiment. In addition, the pores 212 may be much more irregular and serpentine. The schematic illustration is to facilitate a better understanding of the working of the embodiment. In this embodiment, the component body 204 is made of aluminum. In other embodiments, the component body 204 is made of an anodized aluminum or ceramic body. In this embodiment, the electrolytic oxidation coating 208 comprises alumina. In other embodiments, the electrolytic oxidation coating 208 comprises oxides or fluorinated oxides of at least one of aluminum, titanium, or magnesium.

If the component body 204 is a ceramic and/or is not solely metal, a metal layer may be deposited on the surface of the component body 204. The metal layer may be deposited by physical vapor deposition, electrochemical deposition from a solution containing metal ions, or by 3D printing of metal directly on the surface of the component body 204. The electrolytic oxidation would be performed on the deposited metal layer.

In the plasma electrolytic process for an aluminum component body 204, a high voltage of at least 200 volts is applied. The high voltage exceeds the dielectric breakdown potential of an aluminum oxide film creating a discharge and a localized plasma. The high bias, discharge, and plasma create a localized high temperature. These conditions may result in sintering, melting, and densification of the resulting metal oxide. In an embodiment, the thickness of the electrolytic oxidation coating 208 is greater than 25 μm.

A surface treatment is provided to the electrolytic oxidation coating 208 (step 106). In this example, the surface treatment is provided by exposing the electrolytic oxidation coating 208 to a flow of ozone at a temperature in the range from 150° to 320° C. This surface treatment provides a certain level of cleaning and prepares the surface for the subsequent ALD process. It is important that the surface be free of hydrocarbons, water or other contaminants and has activated oxygen radicals to absorb reactants with a metal precursor. In an alternative embodiment, a surface treatment is provided at a high temperature with a plurality of purge cycles of an inert gas to burn off hydrocarbons and eliminate water from the surfaces.

An atomic layer deposition (ALD) process is then provided (step 108). The atomic layer deposition process (step 108) comprises a plurality of cycles. In this example, each cycle comprises providing a first reactant (step 112), purging the first reactant (step 114), providing a second reactant (step 116), and purging the second reactant (step 118). In this embodiment, the component body 204 is maintained at a temperature of between about 150° to 320° C. for deposition of an aluminum oxide (Al₂O₃) ALD film to cover the surface of the pores 212 in the electrolytic oxidation coating 208.

In this embodiment, the providing the first reactant (step 112) comprises providing a flow of 500 to 200 sccm of trimethylaluminum (Al₂(CH₃)₆). The amount of trimethylaluminum varies with reactor size and the number of components 204 placed simultaneously in the reactor. The first reactant forms a first reactant layer, an aluminum containing layer, on the surfaces of the electrolytic oxidation coating 208 including surfaces of the pores 212. The flow of the first reactant is stopped after 10-30 seconds. 10-30 seconds is usually sufficient to form a monolayer of absorbed aluminum (Al) and methyl radicals (CH₃) on the surface of the component body 204.

The purging the first reactant (step 114) comprises flowing nitrogen. The flow of nitrogen displaces remaining first reactant in the reactor.

In this embodiment, the providing the second reactant (step 116) comprises providing a flow of water vapor. The water vapor reacts with the first reactant layer by hydrolyzing the aluminum in the first reactant layer. The flow of the second reactant is stopped after 10-30 seconds.

The purging the second reactant (step 118) comprises flowing nitrogen. The flow of the nitrogen displaces remaining second reactant in the reactor.

Each of the first and second reactants absorbs and reacts on the component body 204 surface in what is defined as a half-cycle. The absorption is limited to one atomic layer. These two reactants build up a thin layer of an ALD film e.g. Al₂O₃, about 1 Å thick. The process is repeated until the desired film thickness is achieved. FIG. 2B is a schematic cross-sectional view of a component body 204 with the electrolytic oxidation coating 208 over a surface of the component body 204 after a plurality of cycles of the atomic layer deposition process (step 108). An atomic layer deposition 216 has been deposited. In this example, after a plurality of cycles, the ALD 216 is only able to partially fill the two pores 212a, 212b due to their width. A third pore 212c is thinner and is completely filled by the ALD 216. The ALD 216 extends through the thickness of the electrolytic oxidation coating 208 to the component body 204. The ALD 216 covers exposed parts of the component body 204 so that the surface of the component body 204 is not exposed. The ALD process is continued and repeated until all of the pores 212 are completely filled (step 108). FIG. 2C is a schematic cross-sectional view of the component body 204 with the electrolytic oxidation coating 208 after the pores 212 have been completely filled by the ALD 216.

The component body 204 is mounted in a plasma processing chamber (step 120). The plasma processing chamber is used to process a substrate (step 124). A plasma is created within the chamber to process the substrate. Such processing may be etching the substrate. The processing the substrate (step 124) exposes the component body 204 to the plasma.

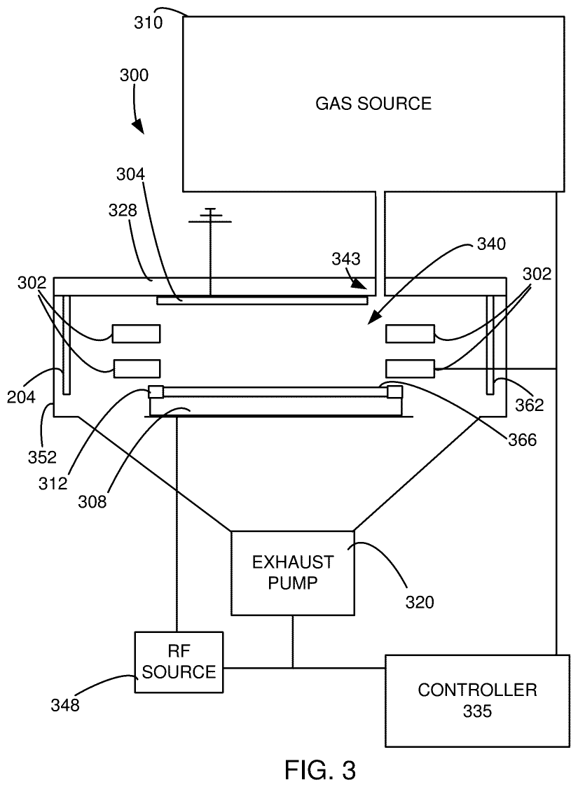

FIG. 3 is a schematic view of a plasma processing chamber 300 with the mounted component body 204. The plasma processing chamber 300 comprises confinement rings 302, an upper electrode 304, a lower electrode 308, a gas source 310, a liner 362, and an exhaust pump 320. In this example, the component body 204 is the liner 362. Within plasma processing chamber 300, a wafer 366 is positioned upon the lower electrode 308. An edge ring 312 surrounds the wafer 366. The lower electrode 308 incorporates a suitable substrate chucking mechanism (e.g., electrostatic, mechanical clamping, or the like) for holding the wafer 366. The reactor top 328 incorporates the upper electrode 304 disposed immediately opposite the lower electrode 308. The upper electrode 304, lower electrode 308, and confinement rings 302 define the confined plasma volume 340.

Gas is supplied to the confined plasma volume 340 through a gas inlet 343 by the gas source 310. The gas is exhausted from the confined plasma volume 340 through the confinement rings 302 and an exhaust port by the exhaust pump 320. A radio frequency (RF) power source 348 is electrically connected to the lower electrode 308.

Chamber walls 352 surround the component body 204, confinement rings 302, the upper electrode 304, and the lower electrode 308. The component body 204 helps prevent gas or plasma that passes through the confinement rings 302 from contacting the chamber walls 352. A controller 335 is controllably connected to the RF power source 348, exhaust pump 320, and the gas source 310. The plasma processing chamber 300 may be a CCP (capacitively coupled plasma) reactor or an ICP (inductively coupled plasma) reactor. Other sources like a surface wave, microwave, or electron cyclotron resonance (ECR) may be used.

Next generations of dielectric memory tools operate at higher RF powers than prior tools. Such next-generation dielectric memory tools have shown arcing failures between the electrostatic chuck (ESC) base plate used for the lower electrode 308 and various edge hardware on the chamber, such as edge rings 312, ground rings and coupling rings. The arcing failures account for >50% of all failures on next-generation tools. To prevent such failures the stand-off voltage of the base plate or other parts must be increased.

Without being bound by theory, it is believed that during plasma processing, chemical adsorbates within the pores 212 of the electrolytic oxidation coating 208 provide a conductive pathway. The conductive pathway can facilitate arcing. Filling the pores 212 with an atomic layer deposition 216 prevents such arcing, leading to improvement in breakdown performance. The ALD material should be non-conducting with a high-resistivity. In addition, the filling to pores 212 with an atomic layer deposition 216 closes the pores 212 to prevent permeation, thus preventing radicals of the plasma from reaching the component body 204.

The resulting electrolytic oxidation coating 208 is resistant to chemical degradation and arcing. In some embodiments, the ALD process (step 108) increases the ability of the electrolytic oxidation coating 208 to withstand arcing by up to 200% on a per unit thickness basis. Experimental data has found that an electrolytic oxidation coating 208 deposited using PEO to a thickness of 50 μm has a standoff voltage of about 1.7 kV (kilovolts) without an ALD 216. The same electrolytic oxidation coating 208 has a standoff voltage of about 3.0-4.0 kV after an ALD 216 has been added. Therefore, the addition of the ALD 216 increases dielectric strength by about two times. As a result, the plasma processing chamber 300 with such components 204 will have fewer defects. In addition, the failure rates of such systems decrease, increasing the time between the replacements of components 204.

In various embodiments, the ALD process (step 108) may be used to form a dielectric atomic layer deposition 216 of a metal containing material such as ceria, zirconia, lanthanum oxide, yttria (Y₂O₃), alumina (Al₂O₃), aluminum nitride (AlN), aluminum carbide (Al₂C₃), or yttrium iodide (Y₂I₃). In some embodiments, a mixture of these film compositions can be utilized e.g. Y₂O₃ can be interlaid with Al₂O₃ to enhance the fluorine corrosion resistance of the electrolytic oxidation coating 208 in a plasma processing chamber 300. Y₂O₃ is created by using an yttrium precursor e.g. yttrium cyclomethapentadiane3 with water vapor. In various embodiments, the dielectric layers of a metal containing material are a metal oxide, metal nitride, metal carbide, or metal iodide. In other embodiments, fluorinated versions of the above materials, such as AlF₃, AlOF, yttrium fluoride (YF₃), or yttrium oxyfluoride (YOF) can be created. In some embodiments, a first reactant may be trimethylaluminum and the second reactant is water vapor. In various embodiments, the ALD process (step 108) may provide alternating layers of different materials. For example, alternating layers of alumina and yttria may be provided in an embodiment. In various embodiments, the first purge (step 114) and/or the second purge (step 118) may not be used.

The electrolytic oxidation coating 208 may have a density of less than 98%, so that the pores 212 make up more than 2% of the electrolytic oxidation coating 208, by volume, providing a porosity of greater than 2%. Preferably, the electrolytic oxidation coating 208 has a thickness of at least 25 μm and less than 500 μm. In another exemplary embodiment, the thickness is between 50 μm and 400 μm. In another exemplary embodiment, the electrolytic oxidation coating 208 has a thickness of at least 200 μm. In another exemplary embodiment, the electrolytic oxidation coating 208 has a thickness of at least 300 μm. For an electrolytic oxidation coating 208 formed by PEO, the porosity may be greater than 20%.

In various embodiments, the component body 204 may be other parts of a plasma processing chamber, such as confinement rings, edge rings 312, the electrostatic chuck, ground rings, chamber liners, door liners, or other components 204. The plasma processing chamber 300 may be a dielectric processing chamber or conductor processing chamber. In some embodiments, one or more, but not all surfaces are coated. Various embodiments provide electrolytic oxidation coatings 208 that allow flat surfaces, cornered radii, high aspect ratio holes, and helium channels. In some embodiments, the component body 204 may be a part made of aluminum. In other embodiments, the component body 204 may be an aluminum part with a surface coating. The surface coating may reduce the thermal mismatch between the aluminum and the electrolytic oxidation coating 208.

Additional processing may be performed on the component body 204 before the component body 204 is mounted in a plasma processing chamber 300 (step 120) or used in a plasma processing chamber 300 (step 124). For example, a second coating may be sprayed over the electrolytic oxidation coating 208. The second coating may have pores. However, since the electrolytic oxidation coating 208 between the second coating and the component body 204 has pores 212 filled with the ALD 216, arcing and chemical degradation is prevented.

In an embodiment, the component body 204 is aluminum and the electrolytic oxidation coating 208 is formed by providing an electrolytic oxidation coating 208 between 0.0005 (0.00127 mm) inches to 0.005 (0.0127 mm) inches thick. In another embodiment, an electrolytic oxidation coating 208 has a thickness of between 0.001 (0.0254 mm) inches to 0.040 inches (1.016 mm). In various embodiments, the pores 212 have a width of less than 1 micron. In some embodiments, using an aluminum containing reactant for atomic layer deposition, a gas transport of greater than 1000:1 is provided at a temperature greater than 300° C. This means that a ratio of the distance that the gas is able to travel through a pore 212 to the width of the pore 212 is greater than 1000:1.

In various embodiments, the first reactant may be an organic molecule attached to a metal-ligand at an end of the organic molecule and second reactants may be an oxidizing agent, such as water vapor or ozone. The organic molecule is reactive at a temperature below the melting point of the material that forms the component body 204. For example, the organic molecule decomposes or is absorbed at a temperature below 50° C.

Various embodiments provide a smooth surface. The resulting surface may be machined. An ALD process is a very slow process but provides a high-quality layer. Various embodiments are able to provide a layer faster than using only a pure ALD process, by using a faster method of forming an electrolytic oxidation coating 208 that is more porous or lower quality than a coating formed by only a pure ALD process. The pores 212 are filled and quality is improved using the ALD process (step 108). As a result, a layer is deposited faster than using only a pure ALD process, with a porosity close to a layer formed by using only a pure ALD process. Since the pores 212 are filled with materials with similar or the same properties as the electrolytic oxidation coating 208, there is no thermal expansion mismatch between the electrolytic oxidation coating 208 and the material filling the pores 212 deposited by the ALD process (step 108). The electrolytic oxidation coating 208 and ALD 216 form a protective layer that does not have polymers. Polymers more easily degrade in plasma. The resulting layer is more corrosion resistant. In various embodiments, when the pores 212 are filled with the ALD 216, the ALD 216 extends through the thickness of the electrolytic oxidation coating 208, so that the component body 204 is not exposed. In various embodiments, the ALD 216 caps the pores 212 so that the component body 204 is not exposed.

In an exemplary embodiment, the ALD 216 fills the pores 212 with minimal pockets. In such an embodiment, the component body 204 is not exposed. In other embodiments, the ALD 216 may have pockets. In such embodiments, the ALD 216 extends to and covers the component body 204, so that the component body 204 is not exposed.

In the above example and other embodiments, the ALD process (step 108) is a plasmaless process. In other embodiments, the ALD process (step 108) uses ozone instead of water vapor. Various embodiments may be performed without a surface treatment step (step 106).

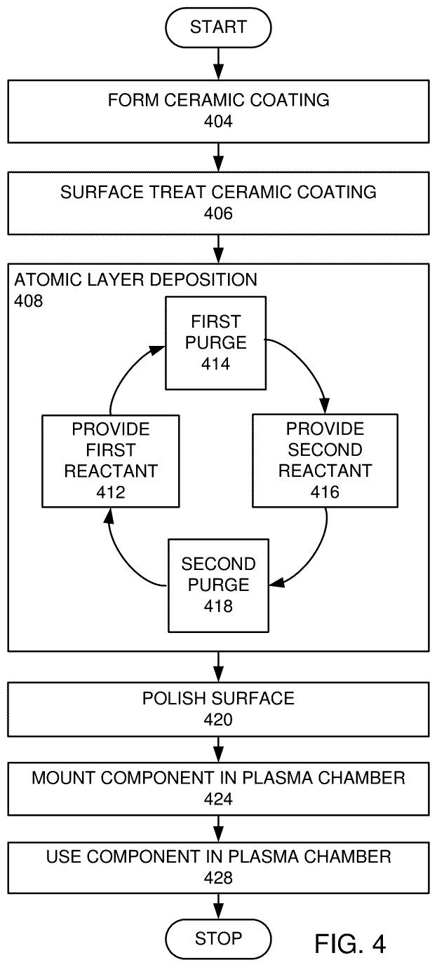

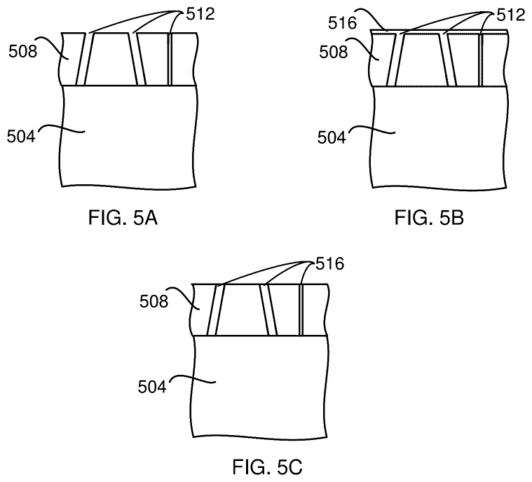

To facilitate understanding, FIG. 4 is a high level flow chart of a process used in another embodiment. In an example of an embodiment, a ceramic coating is formed on a surface of a component (step 404). In this example, the ceramic coating is deposited (step 404) using plasma spraying. FIG. 5A is a schematic cross-sectional view of a component body 504 with a ceramic coating 508. The ceramic coating 508 has been plasma sprayed on a surface of the component body 504. The ceramic coating 508 has a plurality of pores 512, where some of the pores 512 create openings. The openings extend through the thickness of the ceramic coating 508 to the surface of the component body 504. The pores 512 are not drawn to scale but are shown with an enlarged width in order to better illustrate the working of this embodiment. In addition, the pores 512 may be much more irregular and serpentine. The schematic illustration is to facilitate a better understanding of the working of the embodiment. In this embodiment, the component body 504 is made of anodized aluminum. In other embodiments, the component body 504 is made of an aluminum or ceramic body. In this embodiment, the ceramic coating 508 comprises alumina. In other embodiments, the ceramic coating 508 comprises at least one of alumina, yttrium oxide (yttria), aluminum carbide, yttrium iodide ceria, zirconia, fluorinated yttria, aluminum nitride, or lanthanum oxide. In various embodiments, the ceramic coating 508 is applied by one or more of plasma electrolytic oxidation (PEO), anodization, or ceramic spraying.

Plasma spraying is a type of thermal spraying. For plasma spraying, a torch is formed by applying an electrical potential between two electrodes, leading to ionization of an accelerated gas (a plasma). Torches of this type can readily reach temperatures of thousands of degrees Celsius, liquefying high melting point materials such as ceramics. Particles of the desired material are injected into the jet. The particles are melted and accelerated towards the substrate so that the molten or plasticized material coats the surface of the component body 504. The material cools, forming a solid, conformal ceramic coating 508. Plasma spraying processes are distinct from vapor deposition processes. Vapor deposition processes use vaporized material instead of spraying molten material used by plasma spraying processes.

In this embodiment, the thickness of the ceramic coating 508 is greater than 25 μm. In an example of a recipe for plasma spraying the ceramic coating 508, a carrier gas is pushed through an arc cavity and out through a nozzle. In the cavity, a cathode and anode comprise parts of the arc cavity. The cathode and anode are maintained at a large direct current (DC) bias voltage, until the carrier gas begins to ionize, forming the plasma. The hot, ionized gas is then pushed out through the nozzle forming the torch. Into the chamber, near the nozzle, are injected fluidized ceramic particles, tens of micrometers in size. These particles are heated by the hot, ionized gas in the plasma torch to a temperature that exceeds the melting temperature of the ceramic. The jet of plasma and melted ceramic is then aimed at the component body 504. The particles impact the component body 504, flattening and cooling to form the ceramic coating 508.

A surface treatment is provided to the ceramic coating 508 (step 406). In this example, the surface treatment is provided by exposing the ceramic coating 508 to a flow of ozone at a temperature in the range from 150° to 320° C. This surface treatment provides a certain level of cleaning and prepares the surface for the subsequent ALD process. It is important that the surface be free of hydrocarbons or other contaminants and has activated oxygen radicals to absorb the first reactant with a metal precursor.

An atomic layer deposition (ALD) process is then provided (step 408). The atomic layer deposition process (step 408) comprises a plurality of cycles. In this example, each cycle comprises providing a first reactant (step 412), purging the first reactant (step 414), providing a second reactant (step 416), and purging the second reactant (step 418). In this embodiment, the component body 504 is maintained at a temperature of between about 150° to 320° C. for deposition of an aluminum oxide (Al₂O₃) ALD film to cover the surface of the pores 512 in the ceramic coating 508. In this embodiment, the providing the first reactant (step 412) comprises providing a flow of 500 to 200 sccm of trimethylaluminum (Al₂(CH₃)₆). The amount of trimethylaluminum varies with reactor size and number of component bodies 504 placed simultaneously in the reactor. The first reactant forms a first reactant layer, an aluminum containing layer, on the surfaces of the ceramic coating 508 including surfaces of the pores 512. The flow of the first reactant is stopped after 10-30seconds. 10-30 seconds is usually sufficient to form a monolayer of absorbed aluminum (Al) and methyl radicals (CH₃) on the component body 504 surface.

The purging the first reactant (step 414) comprises flowing nitrogen. In this embodiment, the providing the second reactant (step 416) comprises providing a flow of water vapor. The water vapor reacts with the first reactant layer by hydrolyzing the aluminum in the first reactant layer. The flow of the second reactant is stopped after 10-30 seconds. The purging the second reactant (step 418) comprises flowing nitrogen. Each of these reactants absorbs and reacts on the component body 504 surface in what is defined as a half-cycle. The absorption is limited to one atomic layer. These two reactants build up a thin layer of an ALD film e.g. for Al₂O₃ about 1 Å thick. The ALD process is continued until all of the pores 512 are completely filled (step 408). FIG. 5B is a schematic cross-sectional view of the component body 504 with the ceramic coating 508 after the pores 512 have been completely filled by the ALD 516.

The surface is then polished (step 420). In this example, the polishing process removes parts of the ALD 516 that do not fill the pores 512 and may also polish a surface of the component body 504, to provide a smooth polished ALD surface.

The component body 504 is mounted in a plasma processing chamber (step 424). The plasma processing chamber is used to process a substrate (step 428). A plasma is created within the chamber to process the wafer 366. Such processing may be etching a stack on the wafer 366. The processing the wafer 366 (step 428) exposes the component body 504 to the plasma.

In this embodiment, the polishing of the ALD 516 and the component body 504 provides a smoother finished surface. Experiments have found that for plasma spray coatings without an ALD 516 have a dielectric strength of about 20volts/micron. The same coatings have a dielectric strength of about 40 volts/micron and higher after an ALD 516 is added. Therefore, the addition of the ALD 516 increases dielectric strength by about four times.

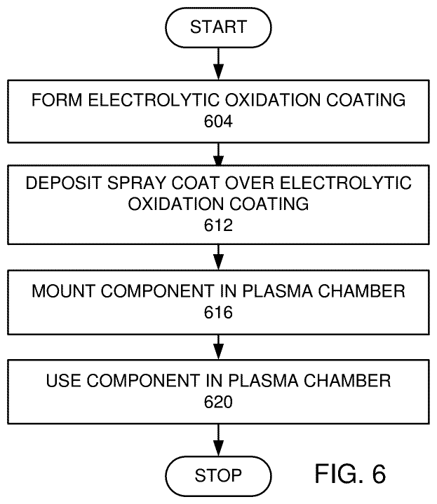

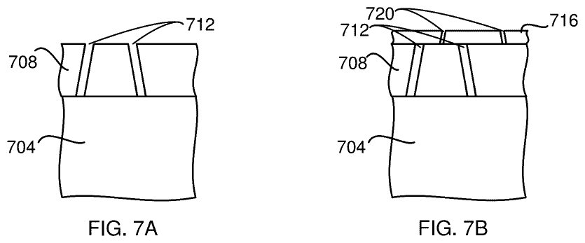

FIG. 6 is a high level flow chart of a process used in another embodiment. In an example of an embodiment, an electrolytic oxidation coating is formed on a surface of a component (step 604). FIG. 7A is a schematic cross-sectional view of a component body 704 with an electrolytic oxidation coating 708. The electrolytic oxidation coating 708 has a plurality of pores 712, where some of the pores 712 create openings. The openings extend through the thickness of the electrolytic oxidation coating 708 to the surface of the component body 704. The pores 712 are not drawn to scale but are shown with an enlarged width in order to better illustrate the working of this embodiment. In addition, the pores 712 may be much more irregular and serpentine. The schematic illustration is to facilitate a better understanding of the working of the embodiment. In this embodiment, the component body 704 is made of aluminum. In this embodiment, the electrolytic oxidation coating 708 comprises oxides or fluorinated oxides of at least one of aluminum, titanium, or magnesium.

A spray coat is deposited over the electrolytic oxidation coating 708 (step 612). FIG. 7B is a schematic cross-sectional view of a component body 704 with an electrolytic oxidation coating 708 after a spray coating 716 has been deposited on the electrolytic oxidation coating 708. The spray coating 716 may partially fill the pores 712 in the electrolytic oxidation coating 708. The spray coating 716 covers the pores 712 in the electrolytic oxidation coating 708. The spray coating 716 has pores 720. Generally, the pores 720 in the spray coating 716 do not align with the pores 712 in the electrolytic oxidation coating 708. However, some of the pores 720 in the spray coating 716 may align with some of the pores 712 in the electrolytic oxidation coating 708. Plasma spray coatings must be dense, to protect the substrate, and thick in order to get high dielectric breakdown voltage. Such a combination is prone to cracking during thermal cycling. If, instead, plasma spray coating is applied over PEO, where the PEO is much more stable during thermal cycling, a less dense spray coat can be applied over it to achieve higher cumulative breakdown voltage. The resulting coating would be less prone to cracking.

While this disclosure has been described in terms of several embodiments, there are alterations, permutations, modifications, and various substitute equivalents, which fall within the scope of this disclosure. It should also be noted that there are many alternative ways of implementing the methods and apparatuses of the present disclosure. It is therefore intended that the following appended claims be interpreted as including all such alterations, permutations, and various substitute equivalents as fall within the true spirit and scope of the present disclosure.

What is claimed is:

1. A method for coating a component of a plasma processing chamber, comprising:
forming an electrolytic oxidation coating over a surface of the component, wherein the electrolytic oxidation coating has a plurality of pores, wherein the electrolytic oxidation coating has a thickness and at least some of the plurality of pores extend through the thickness of the electrolytic oxidation coating; and
depositing an atomic layer deposition on the electrolytic oxidation coating using an atomic layer deposition process, wherein the atomic layer deposition process comprises a plurality of cycles, wherein each cycle comprises:
flowing a first reactant, wherein the first reactant forms a first reactant layer in the pores of the electrolytic oxidation coating, wherein the first reactant layer extends through the thickness of the electrolytic oxidation coating;
stopping the flow of the first reactant;
flowing a second reactant, wherein the second reactant reacts with the first reactant layer; and
stopping the flow of the second reactant.

2. The method, as recited in claim 1, wherein the electrolytic oxidation coating comprises oxides or fluorinated oxides of at least one of aluminum, titanium, or magnesium.

3. The method, as recited in claim 1, wherein the component comprises at least one of aluminum, anodized aluminum, or ceramic.

4. The method, as recited in claim 1, wherein the electrolytic oxidation coating is thicker than 25 μm.

5. The method, as recited in claim 1, wherein a porosity of the electrolytic oxidation coating is greater than 2%.

6. The method, as recited in claim 1, wherein the atomic layer deposition includes at least one of ceria, zirconia, lanthanum oxide, yttria, alumina, aluminum nitride, aluminum carbide, or yttrium iodide.

7. The method, as recited in claim 1, wherein the atomic layer deposition includes alumina.

8. The method, as recited in claim 7, wherein the first reactant comprises trimethylaluminum and the second reactant comprises water vapor or ozone.

9. The method, as recited in claim 1, wherein the depositing an atomic layer deposition on the electrolytic oxidation coating is a plasmaless process.

10. The method, as recited in claim 1, further comprising providing a surface treatment after forming the electrolytic oxidation coating and before depositing the atomic layer deposition.

11. The method, as recited in claim 10, wherein the providing a surface treatment comprises exposing the electrolytic oxidation coating to a flow of ozone or purging with heat and an inert gas.

12. The method, as recited in claim 1, wherein the atomic layer deposition includes alternating layers of at least two of alumina, yttria, ceria, zirconia, or lanthanum oxide.

13. The method, as recited in claim 1, wherein each cycle of the atomic layer deposition process deposits a monolayer.

14. The method, as recited in claim 1, wherein the first reactant comprises an organic molecule with a metal ligand.

15. The method, as recited in claim 14, wherein the second reactant comprises water vapor or ozone.

16. The method, as recited in claim 1, wherein the component includes an electrostatic chuck.

17. The method, as recited in claim 1, further comprising polishing the atomic layer deposition.

18. A method for coating a component of a plasma processing chamber, comprising:
forming a ceramic coating over a surface of the component, wherein the ceramic coating has a plurality of pores, wherein the ceramic coating has a thickness and at least some of the plurality of pores extend through the thickness of the ceramic coating;
depositing an atomic layer deposition on the ceramic coating using an atomic layer deposition process, wherein the atomic layer deposition process comprises a plurality of cycles, wherein each cycle comprises:
flowing a first reactant gas, wherein the first reactant gas forms a first reactant layer in the pores of the ceramic coating, wherein the first reactant layer extends through the thickness of the ceramic coating;
stopping the flow of the first reactant gas;
flowing a second reactant gas, wherein the second reactant gas reacts with the first reactant layer; and
stopping the flow of the second reactant gas; and
polishing away some of the atomic layer deposition.

19. The method, as recited in claim 18, wherein the ceramic comprises at least one of yttria, ceria, zirconia, fluorinated yttria, aluminum nitride, alumina, or lanthanum oxide.
